(19) United States
(12) Patent Application Publication
(10) Pub. No.: US 2008/0078439 A1
(43) Pub. Date: Apr. 3, 2008

(54) POLARIZATION-INDUCED TUNNEL JUNCTION

(76) Inventors: Michael Grundmann, Sunnyvale, CA (US); Umesh K. Mishra, Montecito, CA (US)

Correspondence Address: GATES & COOPER LLP;HOWARD HUGHES CENTER, 6701 CENTER DRIVE WEST, SUITE 1050, LOS ANGELES, CA, 90045, US

(21) Appl. No.: 11/768,105

(22) Filed: Jun. 25, 2007

Related U.S. Application Data
(60) Provisional application No. 60/815,944, filed on Jun. 23, 2006.

(51) Int. Cl. H01L 31/042; H01L 29/06; H01L 31/18

(52) U.S. Cl. 136/249; 257/14; 438/57; 257/E31.005; 257/E29.024

(57) ABSTRACT

A method for electrically connecting semiconductor layers using a layer less than 150 nm thick of a semiconductor material that exhibits strong piezoelectric and/or spontaneous electrical polarization to provide a tunnel junction that electrically connects the semiconductor layers. The semiconductor material that exhibits strong piezoelectric and/or spontaneous electrical polarization comprises an interface between differing (Al,In,Ga)N alloys. The tunnel junction may be between p-type and n-type semiconductor layers, or it may be between two n-type or p-type semiconductor layers. Stacked Schottky diodes or stacked photo-active junctions may be fabricated using this method.

### CROSS-REFERENCE TO RELATED APPLICATIONS

This application claims the benefit under 35 U.S.C Section 119(e) of U.S. Provisional Patent Application Ser. No. 60/815,944, filed on Jun. 23, 2006, by Michael Grundmann and Umesh K. Mishra, entitled “POLARIZATION-INDUCED TUNNEL JUNCTION,” attorney's docket number 30794.186-US-P1 (2006-668), which application is incorporated by reference herein.

This application is related to the following co-pending and commonly-assigned applications:

U.S. Provisional Patent Application Ser. No. 60/908,919, filed on Mar. 29, 2007, by Umesh K. Mishra, Michael Grundmann, Steven P. DenBaars, and Shuji Nakamura, entitled “DUAL SURFACE-ROUGHENED N-FACE HIGH-BRIGHTNESS LED,” attorney's docket number 30794.217-US-P1 (2007-279); and

U.S. Provisional Patent Application Ser. No. 60/940,052, filed on May 24, 2007, 2007, by Umesh K. Mishra, Tomas Palacios, and Man Hoi Wong, entitled “POLARIZATION-INDUCED BARRIERS FOR N-FACE NITRIDE-BASED ELECTRONICS,” attorney's docket number 30794.228-US-P1 (2006-648);

which applications are incorporated by reference herein.

### STATEMENT REGARDING FEDERALLY SPONSORED RESEARCH AND DEVELOPMENT

This invention was made with Government support under Grant No. N00014-05-1-0419 awarded by the Office of Naval Research (ONR). The Government has certain rights in this invention.

### BACKGROUND OF THE INVENTION

1. Field of the Invention

This invention relates to polarization-induced tunnel junctions for photovoltaic applications.

2. Description of the Related Art

In the prior art, electrical connection between solid-state devices has been accomplished using metallic layers, such as solder or tunnel junctions that are comprised of highly doped p/n junctions.

Nitrides have additional flexibility afforded by polarization. In the nitride material system, any interface between differing AlInGaN alloys exhibits sheet charges that arise from the difference in net polarization between the layers. These layers have an inherent electric field that is induced by the polarization charges that may be used to provide the dipole moment needed in a p/n junction instead of using other space charge in the junction.

In addition, the electric field provided by the polarization charges may be larger than what can be provided by ionized donors and acceptors alone. Using this polarization-induced electric field, with or without the additional electric field provided by ionized donors and acceptors, the depletion region of the junction may be made small enough to enable efficient tunneling transport even in large band-gap semiconductor systems.

### SUMMARY OF THE INVENTION

The present invention enables tunnel junctions in semiconductor systems that exhibit electrical polarization. Compared to normal highly doped tunnel junctions, this tunnel junction does not need doping, since the dipole moment is supplied by the polarization charges alone.

The present invention enables several novel device designs that are otherwise unavailable using standard bipolar tunnel junction designs. For example, the present invention makes stacked wide band-gap photovoltaic cells feasible.

The present invention discloses a method for electrically connecting semiconductor layers, comprising using a layer less than 150 nm thick of a semiconductor material that exhibits electrical polarization (such as piezoelectric and/or spontaneous electrical polarization) to provide a tunnel junction that electrically connects the semiconductor layers. The semiconductor material that exhibits electrical polarization may comprise an interface between differing (Al,In,Ga)N alloys. The tunnel junction may be between intrinsic, p-type and n-type semiconductor layers, or two n-type or p-type semiconductor layers, or unintentionally doped layers.

One or more stacked photoactive junctions may be fabricated using the method, wherein the stacked photoactive junctions are stacked on either side of the tunnel junction to create a series junction with a larger V_{oc} and efficiency than a single junction for photovoltaic applications. One or more stacked Schottky diodes may be fabricated by making a Schottky contact to one or more of the semiconductor layers.

The present invention also discloses a polarization-induced tunnel junction comprised of a tunneling layer clad by a first semiconductor layer and a second semiconductor layer, wherein the tunneling layer has a different electrical polarization than the first semiconductor layer or the second semiconductor layer, or the first semiconductor layer and the second semiconductor layer, and the different electrical polarization provides a dipole moment to electrically connect the first semiconductor layer and the second semiconductor layer.

The tunneling layer may be InGaN, the first semiconductor layer may be GaN, and the second semiconductor layer may be InGaN with a lower In composition than the tunneling layer. The tunneling layer may be strained c-plane metal-face InGaN. The first semiconductor layer and the second semiconductor layer may be intrinsic, p-type, or n-type, both n-type, or both p-type, or unintentionally doped. The tunneling layer may comprise graded (Al,In,Ga)N to provide polarization-based doping. The cladding layers may also be graded alloys of (Al,In,Ga)N in order to maximize light absorption and/or to provide polarization-based doping in the absorbing layers.

The present invention also discloses a polarization-induced tunnel junction with p/n homojunctions, on either side of the tunnel junction, that act as photovoltaic cells in series. This device comprises a p-type layer on the first semiconductor layer, wherein the first semiconductor layer is n-type and forms a first p/n junction with the p-type layer; the second semiconductor layer on an n-type layer, wherein the second semiconductor layer is p-type and forms a second p/n junction with the n-type layer; and ohmic contacts to the p-type layer and the n-type layer.

The first p/n junction, second p/n junction, or both the first p/n junction and second p/n junction may be heterostructures with a narrower band gap material clad with larger band-gap material to increase minority carrier lifetimes.

The polarization-induced tunnel junction may further comprise a Schottky contact to the first semiconductor layer and an ohmic contact to the second semiconductor layer, to form a solar cell.

The tunneling layer, first semiconductor layer and second semiconductor layer may be comprised of (Al,In,Ga)N or ZnBeMgCdO alloys tuned to maximize tunneling current and efficiency of the photovoltaic cells. The tunneling layer may be AlN to ensure a p-up structure, for example, in Ga-face c-plane GaN. The tunneling layer may comprise material with a smaller bandgap than the first semiconductor and the second semiconductor layers' bandgaps, to improve tunneling currents. The first semiconductor layer and second semiconductor layer may have smaller bandgaps than the tunneling layer's bandgap, to improve tunneling currents. At least one active layer may be on the polarization induced tunnel junction such that the active layer is clad by wider band gap materials.

The polarization-induced tunnel junction may be a quantum well to decrease an absorption length of the polarization-induced tunnel junction, and may comprise semi-polar or non-polar material. The polarization-induced tunnel junction may be formed on a nano-patterned substrate, wherein the tunneling layer comprises the quaternary compound AlInGaN to maximize the polarization differences in the tunnel junction.

### BRIEF DESCRIPTION OF THE DRAWINGS

Referring now to the drawings in which like reference numbers represent corresponding parts throughout:

FIG. 1 is a tunnel junction band diagram illustrating depth (nm) vs. energy (eV) of E_{c} (conduction band edge), Eᵥ (valence band edge) and E_{f} (Fermi energy level), for an In_{0.2}Ga_{0.8}N—In_{0.5}Ga_{0.5}N—GaN tunnel junction, showing a large polarization-induced electric field and narrow depletion width.

FIG. 2 is a band diagram illustrating depth from surface (nm) vs. energy (eV) of E_{c}, Eᵥ and E_{f} for a GaN—In_{0.2}Ga_{0.8}N tandem p/n junction solar cell, with a In_{0.2}Ga_{0.8}N—In_{0.5}Ga_{0.5}N—GaN polarization-induced tunnel junction.

FIG. 3 is a schematic diagram of a GaN—In_{0.2}Ga_{0.8}N tandem p/n junction solar cell with a In_{0.2}Ga_{0.8}N—In_{0.5}Ga_{0.5}N—GaN tunnel junction.

FIG. 4 is a band diagram illustrating depth (nm) vs. energy (eV) of E_{c}, Eᵥ and E_{f} for a GaN—In_{0.2}Ga_{0.8}N tandem Schottky solar cell, with a In_{0.2}Ga_{0.8}N—In_{0.5}Ga_{0.5}N—GaN polarization-induced tunnel junction.

FIG. 5 is a schematic diagram of a GaN—In_{0.2}Ga_{0.8}N tandem Schottky solar cell with a In_{0.2}Ga_{0.8}N—In_{0.5}Ga_{0.5}N—GaN tunnel junction.

FIG. 6 is a graph of current density versus forward bias for two polarization-induced Schottky junctions with different AlN thicknesses, 35 Å and 17 Å.

FIG. 7 shows current-voltage (I-V) curves for the 35 Å AlN interlayer sample of FIG. 6 illuminated with high-intensity discharge (HID) light.

FIG. 8 is a schematic of the device structure for the sample measured in FIG. 7.

FIG. 9 is a flowchart illustrating a method of electrically connecting semiconductor layers, according to a preferred embodiment of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The general purpose of the present invention is to provide a method to electrically connect electronically-active and/or photo-active semiconductor layers, such as photovoltaic cells, using electrically polarized semiconductors. The present invention also describes solar cells using polarization to induce band bending.

Technical Description

The proposed device structures of the present invention use a thin layer (<150 nm) of material that exhibits strong electrical polarization compared to essentially non-polar materials such as GaAs, typically on the order of 1×10⁻⁹ to 1×10⁻⁵ C/cm², with contributions from piezoelectric and/or spontaneous electrical polarization, to provide an effective tunnel junction. As noted above, in the nitride material system, any interface between differing AlInGaN alloys exhibits sheet charges that arise from the difference in net polarization between the layers. These layers have an inherent electric field that is induced by the polarization charges, that may be used to provide the dipole moment needed in a p/n junction instead of using other space charge in the junction. In addition, the electric field provided by the polarization charges may be larger than what can be provided by ionized donors and acceptors alone. Using this polarization-induced electric field, with or without the additional electric field provided by ionized donors and acceptors, the depletion region of the junction may be made small enough (3 nm for GaN) to enable efficient tunneling transport even in large band-gap semiconductor systems. In comparison, to produce a highly-doped junction for GaN, with a band-gap of 3.4 eV, doping-related material quality issues limit the junction width to 10 nm.

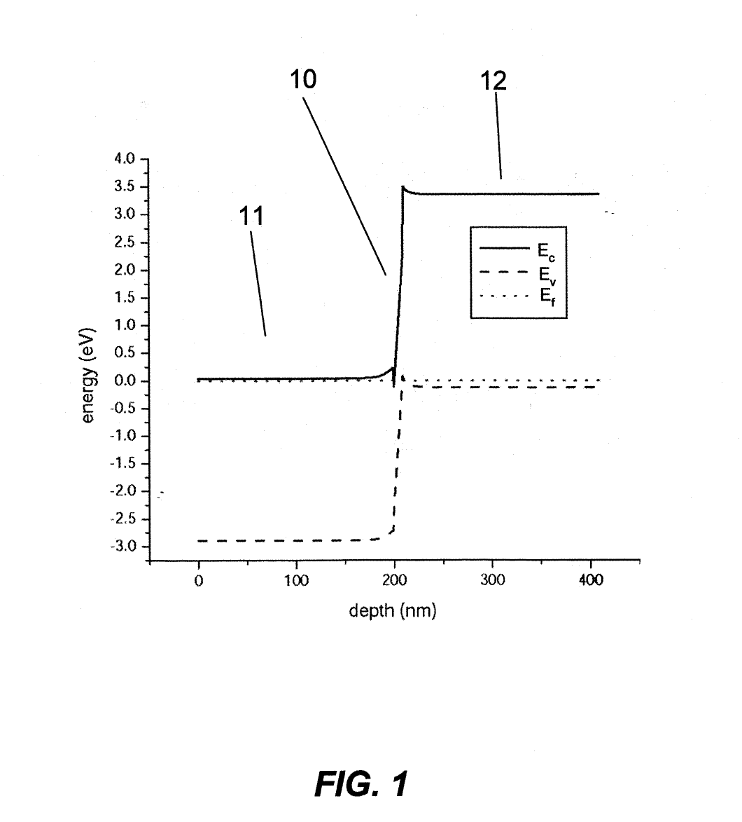

FIG. 1 is a tunnel junction band diagram illustrating depth (nm) vs. energy (eV) of E_{c} (conduction band edge), Eᵥ (valence band edge) and E_{f} (Fermi energy level) for an In_{0.2}Ga_{0.8}N—In_{0.5}Ga_{0.5}N—GaN tunnel junction showing a large polarization-induced electric field on the order of MV/cm and narrow depletion width.

In addition to providing an efficient tunnel junction between p-type and n-type layers, this tunnel junction design allows for bipolar tunnel junctions to be constructed between two n-type or p-type layers, since the dipole moment needed to construct such a junction can be provided by polarization charge alone. This allows the fabrication of stacked Schottky diodes. Using these polarization-induced tunnel junctions, photo-active (photovoltaic) junctions may be stacked to create a series junction with a larger V_{oc} (open circuit voltage) and efficiency than a single junction for photovoltaic applications.

The device that is most promising has a polarization-induced tunnel junction comprised of strained c-plane metal-face InGaN as the tunneling layer 10, clad by GaN 11 on the upper side and InGaN 12 on the lower side. In one embodiment, the In composition of the layer 12 is lower than the In composition of the layer 10.

On either side of the tunnel junction formed by 10, 11, 12 are p/n homojunctions that act as photovoltaic cells in series (not shown). This structure may be grown by Molecular Beam Epitaxy (MBE), Metalorganic Chemical Vapor Deposition (MOCVD), or any other growth system that allows for good control over layer composition and thickness. The structure may be etched to reveal lower n-type contact layers, and then upper and lower ohmic contacts may be deposited. Anti-reflective coatings and a backside mirror may be added to improve efficiency.

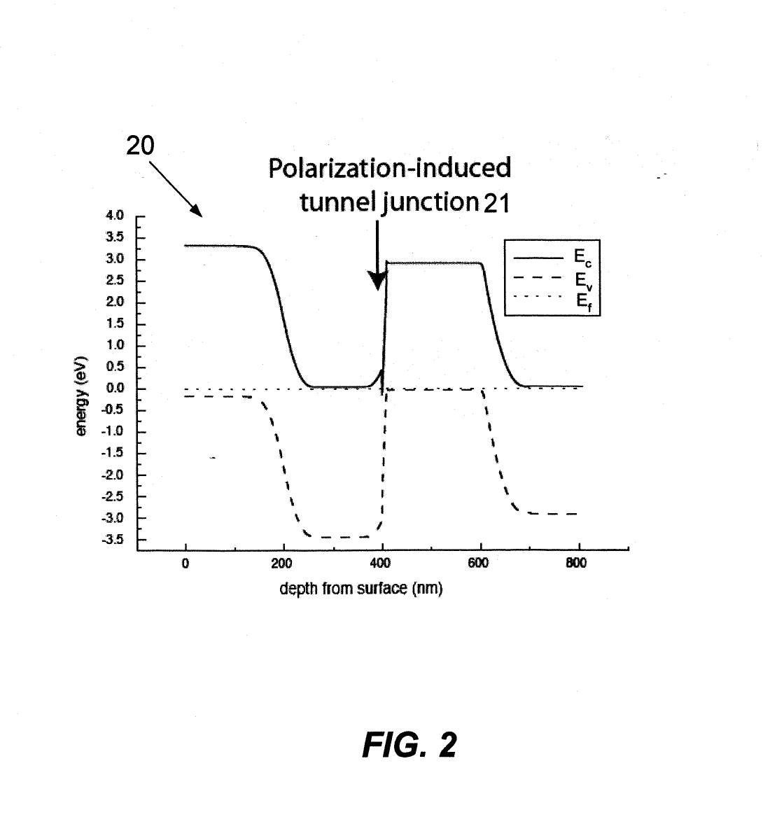

FIG. 2 is a tunnel junction band diagram illustrating depth from surface (nm) vs. energy (eV) of E_{c}, Eᵥ and E_{f} for a GaN—In_{0.2}Ga_{0.8}N tandem p/n junction solar cell 20 with an In_{0.2}Ga_{0.8}N—In_{0.5}Ga_{0.5}N—GaN tunnel junction 21.

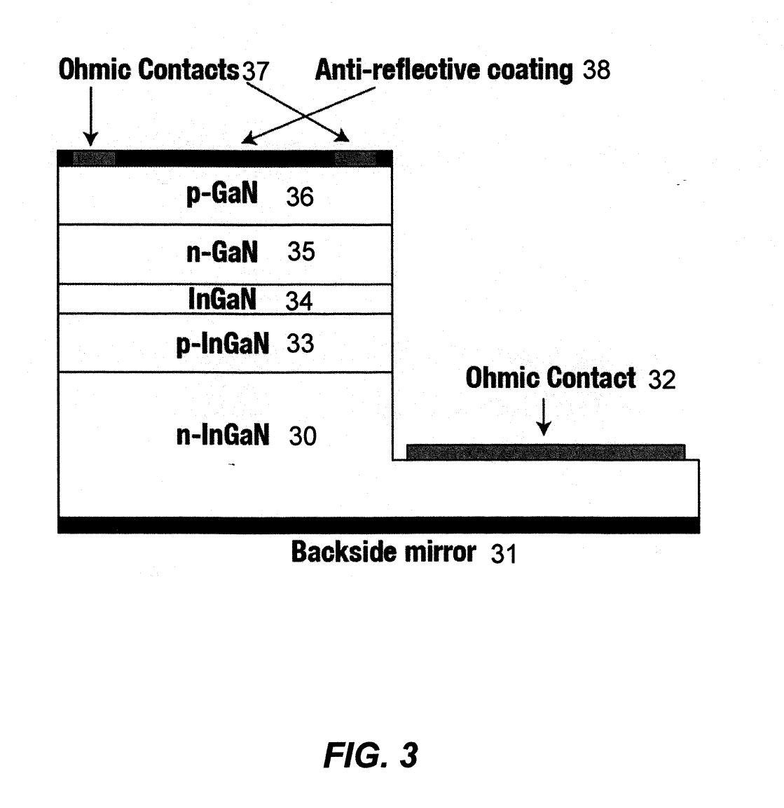

FIG. 3 is a schematic diagram of a GaN—In_{0.2}Ga_{0.8}N tandem p/n junction solar cell with an In_{0.2}Ga_{0.8}N—In_{0.5}Ga_{0.5}N—GaN tunnel junction. The solar cell comprises a base n-InGaN layer 30 having a backside mirror 31 on one side and an ohmic contact 32 near the edge on the other side, a p-InGaN layer 33 on top of the base n-InGaN layer 30, an InGaN tunneling layer 34 (with higher In composition than the cladding layers 33, 35) on top of the p-InGaN layer 33, an n-GaN layer 35 on top of the InGaN layer 34, a p-GaN layer 36 on top of the n-GaN layer 35, and ohmic contacts 37 and anti-reflective coating 38 on top of the p-GaN layer 36. Note that this device is usually grown on a template comprised of GaN on sapphire or SiC.

Possible Modifications

Although specific alloys are described herein, the composition is not fixed, and other alloys may be used.

The photovoltaic junctions described above in the Technical Description section may be replaced with Schottky junctions. The polarization-induced tunnel junctions provide for the necessary band-bending needed in a stacked photovoltaic cell and provide the necessary current path for both minority and majority carriers.

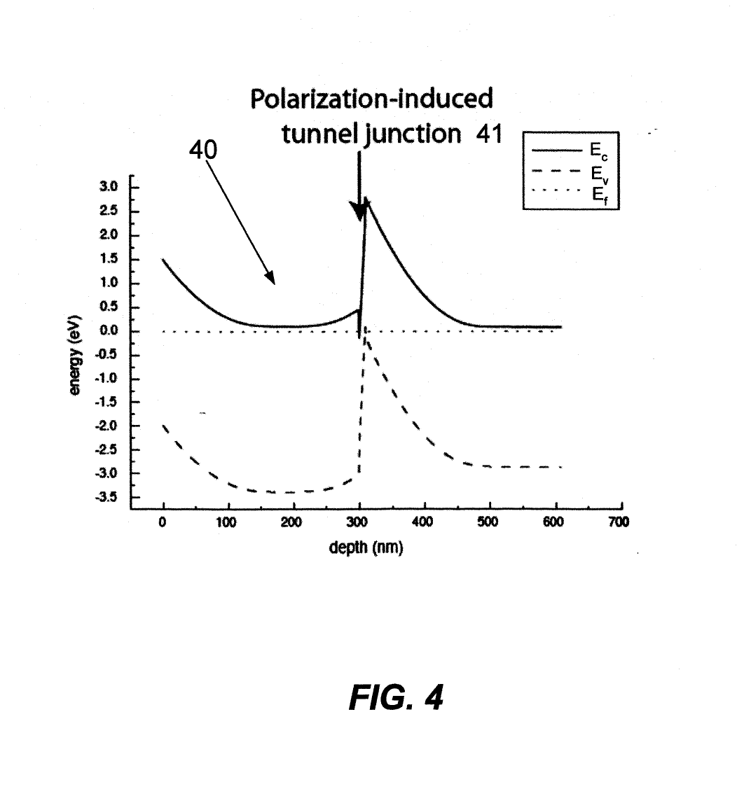

FIG. 4 is a tunnel junction band diagram illustrating depth (nm) vs. energy (eV) of E_{c}, Eᵥ and E_{f} for a GaN—In_{0.2}Ga_{0.8}N tandem Schottky solar cell 40 with an In_{0.2}Ga_{0.8}N—In_{0.5}Ga_{0.5}N—GaN tunnel junction 41.

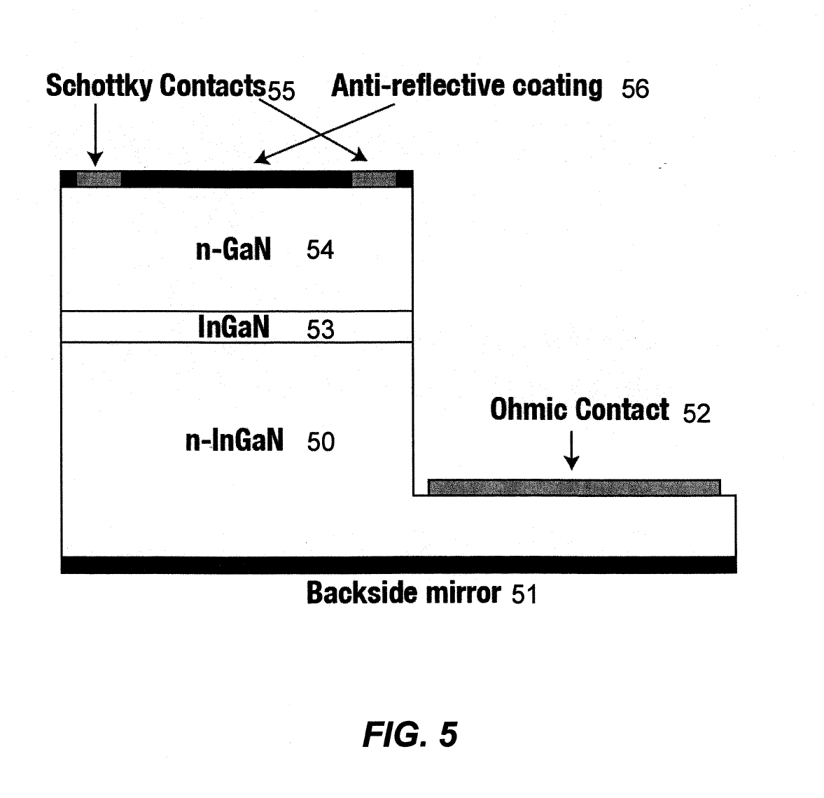

FIG. 5 is a schematic diagram of a GaN—In_{0.2}Ga_{0.8}N tandem Schottky solar cell with an In_{0.2}Ga_{0.8}N—In_{0.5}Ga_{0.5}N—GaN tunnel junction. The solar cell includes a base n-InGaN layer 50 having a backside mirror 51 on one side and an ohmic contact 52 near the edge on the other side, an InGaN tunneling layer 53 on top of the base n-InGaN layer 50, an n-GaN layer 54 on top of the InGaN layer 53, and two Schottky contacts 55 and anti-reflective coating 56 on top of the n-GaN layer 54.

The tunnel junction material described above in the Technical Description section may be replaced with any AlInGaN alloy. For example, a device grown on the N-face of a wurtzite nitride may use AlN instead to ensure a p-type material is at the growth surface, for example, in Ga-face c-plane GaN. The structure described above in the Technical Description section may be grown on nano-patterned substrates. In this case, piezoelectric polarization is drastically reduced due to strain management, so the quaternary compound AlInGaN may be used to maximize the differences in spontaneous polarization in the tunnel junction.

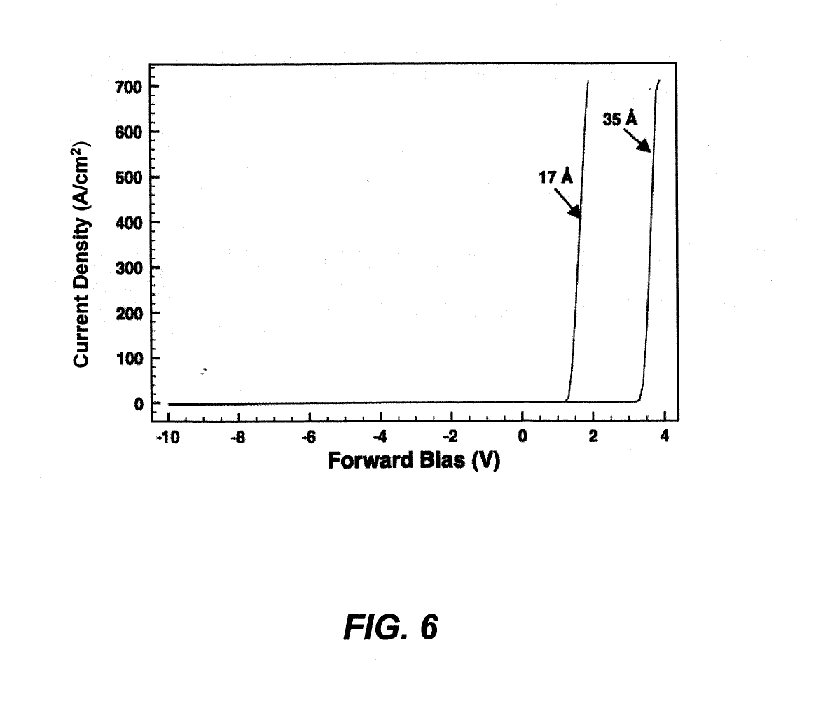

FIG. 6 is a graph of current density versus forward bias for two polarization-induced Schottky junctions with different AlN thicknesses: 35 Angstroms (Å) thick and 17 Å thick. The turn-on of each junction is determined by the polarization-induced band offset in the Schottky-like junction, which changes linearly with AlN thickness. The 35 Å thick sample is a good candidate for solar cell applications, due to the offset equaling the band-gap of GaN (3.4 eV).

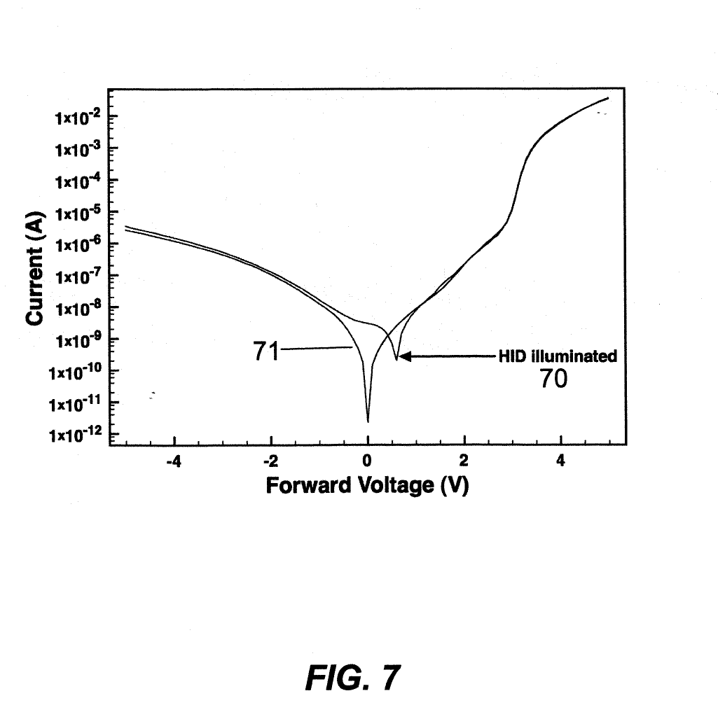

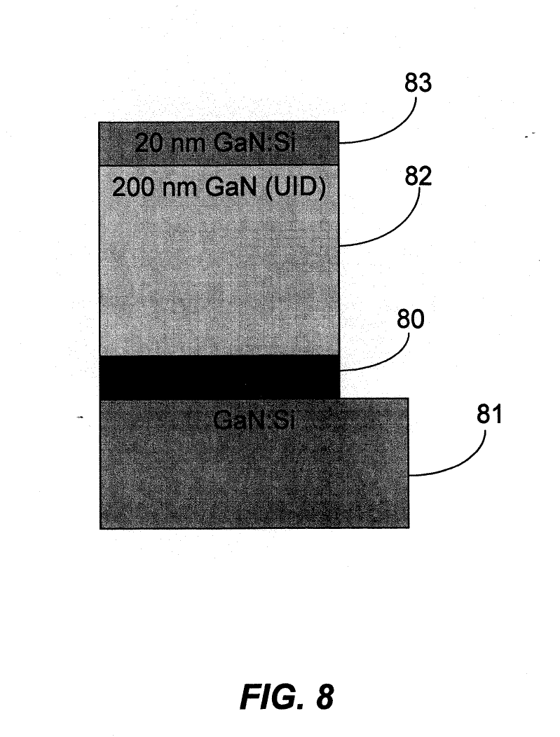

FIG. 7 shows current-voltage (I-V) curves for the 35 Å AlN interlayer sample illuminated with an HID light 70 and not illuminated with light 71. The illumination area is 75 um×10 um, while the device area is 75×75 μm. The illuminated sample clearly shows increase reverse bias current and a shift in the zero current voltage, indicating current transport through the tunnel junction. The device structure for the samples measured in FIGS. 6 and 7 is shown in FIG. 8, and comprises an AlN layer 80 (17 Å or 35 Å thick, for example) on GaN:Si 81, a 200 nm thick unintentionally doped (UID) GaN layer 82 on the AlN layer 80, and a 20 nm thick GaN:Si layer 83 on the UID layer 82.

The materials described above in the Technical Description section may be replaced with oxide alloys ZnBeMgCdO or other semiconductors that exhibit strong polarization properties tuned to maximize tunneling current and photovoltaic response.

The cladding layers adjacent the tunneling layer in FIGS. 1-5 may also comprise any semiconductor material layers so long as at least one cladding layer has a different polarization than the tunneling layer. This is typically achieved by fabricating the cladding layers from different alloy composition semiconductor layers than the tunneling layer.

The lower n-type contacts for the device described above in the Technical Description section may be deposited on a conducting substrate, negating the need for an etch to reveal lower n-type contact layers.

The p/n junctions described above in the Technical Description section may contain a double heterostructure with a narrower band-gap material clad with larger band-gap material to increase minority carrier lifetimes.

The p/n junctions described above in the Technical Description section may contain quantum wells to decrease the absorption length and/or increase device efficiency.

A tunnel junction may be used in the device described above in the Technical Description section to circumvent the need to contact a p-type region. Typical p-type contacts for nitrides exhibit high contact resistances, and p-type material is prone to high sheet resistances due to poor carrier mobility and high activation energy of dopants. Using a tunnel junction at the upper p-type layer one can instead contact an overlying n-type contact.

Graded AlInGaN may be used in the junctions to enable polarization-based doping and/or increase the efficiency of each junction in the stacked device.

This device can be grown on any polar or semi-polar axis, with changes made to the respective AlInGaN compositions corresponding to the difference in polarization.

This tunnel junction design is superior to current state-of-the-art designs in that it does not require high doping, or doping at all to be effective. In addition, it enables higher tunneling currents in large band-gap systems that are unavailable with doping alone due to the narrow nature of the tunnel barrier. It also allows for stacked device designs without the need for separate material depositions as in a soldered or metallically connected design.

Process Steps

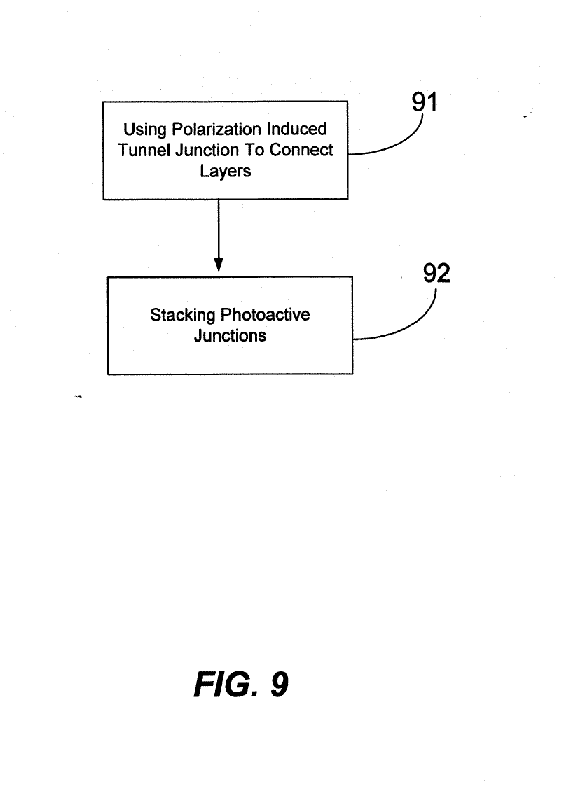

FIG. 9 is a flowchart illustrating a method of electrically connecting semiconductor layers, according to a preferred embodiment of the present invention.

Block 91 represents the step of using a layer less than 150 nm thick of a semiconductor material that exhibits electrical polarization to provide a tunnel junction that electrically connects the semiconductor layers. The semiconductor material that exhibits electrical polarization may comprise an interface between differing (Al,In,Ga)N alloys. The tunnel junction may be between p-type and n-type semiconductor layers or between two n-type or p-type semiconductor layers.

Block 92 represents the step of stacking photoactive junctions on either side of the tunnel junction to create a series junction with a larger V_{oc} and efficiency than a single junction for photovoltaic applications. The photoactive junctions may be p/n junctions or Schottky diodes, for example. One or more stacked Schottky diodes fabricated may be formed by making a Schottky contact to one or more of the semiconductor layers.

The end result of the steps is shown in FIGS. 1-5 and 8, which illustrate a polarization-induced tunnel junction comprised of a tunneling layer 10, 34, 53 and 80 clad by a first semiconductor layer 11, 35, 54 and 82, and a second semiconductor layer 12, 33, 50 and 81, wherein:

(1) the tunneling layer 10, 34, 53 and 80 has a different electrical polarization than the first semiconductor layer 11, 35, 54 and 82 or the second semiconductor layer 12, 33, 50, and 81, or the first semiconductor layer 11, 35, 54 and 82 and the second semiconductor layer 12, 33, 50, and 81,

(2) the different electrical polarization provides a dipole moment to electrically connect the first semiconductor layer 11, 35, 54 and 82 and the second semiconductor layer 12, 33, 50 and 81.

As noted above, the first semiconductor layer and the second semiconductor layer may be p-type or n-type, both n-type, or both p-type, or unintentionally doped. The tunneling layer, first semiconductor layer and second semiconductor layer may be comprised of (Al,In,Ga)N or ZnBeMgCdO alloys tuned to maximize tunneling current and efficiency of the photovoltaic cells. The tunneling layer may be InGaN, the first semiconductor layer may be GaN, and the second semiconductor layer may be InGaN with a lower In composition than the tunneling layer.

The present invention, as illustrated in block 92 of FIG. 9 for example, allows any number of semiconductor layers (for example, active layers), comprising various alloys and various bandgaps, to be stacked on either side of the polarization-induced tunnel junction. The tunneling layer may comprise material with a smaller bandgap than the first semiconductor layer's bandgap and the second semiconductor layer's bandgap, to improve tunneling currents. For example, a device may comprise three or more materials with different bandgaps. In this application, one layer is used as the tunnel junction, which does not directly contact the active layer itself. The active layer is clad by wider band gap materials that act as a window but have better electrical properties, for example.

Another application uses smaller bandgap materials right next to the tunneling layer to improve tunneling currents. In this case, the first semiconductor layer and second semiconductor layer have smaller bandgaps than the tunneling layer's bandgap, to improve tunneling currents.

As noted above, FIG. 3 illustrates a polarization-induced tunnel junction comprising a p-type layer 36 on the first semiconductor layer 35, wherein the first semiconductor layer 35 is n-type and forms a first p/n junction with the p-type layer 36, and the second semiconductor layer 33 on an n-type layer 30, wherein the second semiconductor layer 33 is p-type and forms a second p/n junction with the n-type layer 30. The first p/n junction and second p/n junction act as photovoltaic cells in series. FIG. 3 also illustrates ohmic contacts 32, 37 to the p-type layer and the n-type layer.

Also as noted above, FIG. 5 illustrates a device comprising one or more Schottky contacts 55 to the first semiconductor layer 54 and an ohmic contact 52 to the second semiconductor layer 50, to form a solar cell.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for electrically connecting semiconductor layers, comprising:
using a layer less than 150 nm thick of a semiconductor material that exhibits electrical polarization to provide a tunnel junction that electrically connects the semiconductor layers.

2. The method of claim 1, wherein the semiconductor material that exhibits the electrical polarization comprises an interface between differing (Al,In,Ga)N alloys.

3. The method of claim 1, wherein the electrical polarization is piezoelectric or spontaneous electrical polarization.

4. The method of claim 1, wherein the tunnel junction is between p-type and n-type semiconductor layers.

5. The method of claim 1, wherein the tunnel junction is between two n-type or p-type semiconductor layers.

6. One or more stacked photoactive junctions fabricated using the method of claim 1, wherein the stacked photoactive junctions are stacked on either side of the tunnel junction to create a series junction with a larger V_{oc} and efficiency than a single junction for photovoltaic applications.

7. One or more stacked Schottky diodes fabricated using the method of claim 6, formed by making a Schottky contact to one or more of the semiconductor layers.

8. A polarization-induced tunnel junction, comprising:
a tunneling layer clad by a first semiconductor layer and a second semiconductor layer, wherein:
the tunneling layer has a different electrical polarization than the first semiconductor layer or the second semiconductor layer, or the first semiconductor layer and the second semiconductor layer, and
the different electrical polarization provides a dipole moment to electrically connect the first semiconductor layer and the second semiconductor layer.

9. The polarization-induced tunnel junction of claim 8, wherein the tunneling layer is InGaN, the first semiconductor layer is GaN, and the second semiconductor layer is InGaN with a lower In composition than the tunneling layer.

10. The polarization-induced tunnel junction of claim 9, wherein the tunneling layer is strained c-plane metal-face InGaN.

11. The tunnel junction of claim 8, wherein the first semiconductor layer and the second semiconductor layer are p-type or n-type, both n-type, or both p-type, or unintentionally doped.

12. The polarization-induced tunnel junction of claim 8, wherein the tunneling layer comprises graded (Al,In,Ga) N to provide polarization-based doping.

13. The polarization-induced tunnel junction of claim 8, wherein, on either side of the tunnel junction, are p/n homojunctions that act as photovoltaic cells in series.

14. The polarization-induced tunnel junction of claim 8, further comprising:
a p-type layer on the first semiconductor layer, wherein the first semiconductor layer is n-type and forms a first p/n junction with the p-type layer; and the second semiconductor layer on an n-type layer, the second semiconductor layer is p-type and forms a second p/n junction with the n-type layer, and the first p/n junction and second p/n junction act as photovoltaic cells in series; and
ohmic contacts to the p-type layer and the n-type layer.

15. The polarization-induced tunnel junction of claim 14, wherein the tunneling layer, first semiconductor layer and second semiconductor layer are comprised of (Al,In,Ga)N or ZnBeMgCdO alloys tuned to maximize tunneling current and efficiency of the photovoltaic cells.

16. The polarization induced tunnel junction of claim 14, wherein the first p/n junction, second p/n junction, or both the first p/n junction and second p/n junction are heterostructures with a narrower band gap material clad with larger band-gap material to increase minority carrier lifetimes.

17. The polarization-induced tunnel junction of claim 8, further comprising a Schottky contact to the first semiconductor layer and an ohmic contact to the second semiconductor layer, to form a solar cell.

18. The polarization-induced tunnel junction of claim 8, formed on a nano-patterned substrate, wherein the tunneling layer comprises the quaternary compound AlInGaN to maximize the polarization differences in the tunnel junction.

19. The polarization-induced tunnel junction of claim 8, wherein the tunneling layer is AlN to ensure a p-up structure in Ga-face c-plane GaN.

20. The polarization-induced tunnel junction of claim 8, wherein the tunneling layer comprises material with a smaller bandgap than the first semiconductor layer's bandgap and the second semiconductor layer's bandgap, to improve tunneling currents.

21. The polarization-induced tunnel junction of claim 8, further comprising at least one active layer on the polarization induced tunnel junction such that the active layer is clad by wider band gap materials.

22. The polarization-induced tunnel junction of claim 8, wherein the first semiconductor layer and second semiconductor layer have smaller bandgaps than the tunneling layer's bandgap, to improve tunneling currents.

23. The polarization-induced tunnel junction of claim 8, wherein the polarization-induced tunnel junction is a quantum well to decrease an absorption length of the polarization-induced tunnel junction.

24. The polarization-induced tunnel junction of claim 8, comprising semi-polar or non-polar material.
